(19) United States
(12) Patent Application Publication
(10) Pub. No.: US 2008/0135758 A1
(43) Pub. Date: Jun. 12, 2008

(54) BOLOMETER AND METHOD OF MANUFACTURING THE SAME

(75) Inventors: Woo Seok YANG, Daejeon-City (KR); Seong Mok Cho, Daejeon-City (KR); Hojun Ryu, Seoul (KR); Byoung Gon Yu, Daejeon-City (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon-city (KR)

(21) Appl. No.: 11/776,945

(22) Filed: Jul. 12, 2007

(30) Foreign Application Priority Data
Dec. 6, 2006 (KR) 10-2006-0123416
Apr. 24, 2007 (KR) 10-2007-0040047

(51) Int. Cl. G01J 5/00; H01L 21/00; H01L 27/14

(52) U.S. Cl. 250/338.1; 438/72; 257/E21.001

(57) ABSTRACT

Provided are a bolometer and a method of manufacturing the bolometer. The bolometer includes: a semiconductor substrate comprising a detection circuit; a reflective layer disposed in an area of a surface of the semiconductor substrate; metal pads disposed on the surface of the semiconductor substrate beside both sides of the reflective layer to keep predetermined distances from the both sides of the reflective layer; and a sensor structure forming a space corresponding to quarter of an infrared wavelength (λ/4) from a surface of the reflective layer and positioned above the semiconductor substrate, wherein the sensor structure includes: a body including a polycrystalline resistive layer formed of one of doped Si and Si₁₋ₓGeₓ (where x=0.2˜0.5) to be positioned above the reflective layer; and support arms positioned outside the body to be electrically connected to the metal pads.

### CROSS-REFERENCE TO RELATED PATENT APPLICATION

This application claims the benefits of Korean Patent Application No. 10-2006-0123416, filed on Dec. 6, 2006, and Korean Patent Application No. 10-2007-0040047, filed on Apr. 24, 2007, in the Korean Intellectual Property Office, the disclosures of which are incorporated herein in their entirety by reference.

### BACKGROUND OF THE INVENTION

1. Field of the Invention

The present invention relates to a bolometer and a method of manufacturing the same, and more particularly, to a bolometer using a silicon (Si) or silicon germanium (SiGe) resistor manufactured on a semiconductor substrate including an integrated circuit (IC) and a method of manufacturing the same.

2. Description of the Related Art

An infrared sensor is classified into a cooled type infrared (IR) sensor which operates in a liquid nitrogen temperature and a uncooled type infrared sensor which operates at a room temperature. The cooled infrared sensor is a device which senses pairs of electrons and holes, which are generated when a semiconductor material having a small band gap such as HgCdTe absorbs infrared rays, using photoconductors, photodiodes, and photocapacitors. The uncooled infrared sensor is a device which senses variations of electric conductivity or capacitance induced by heat generated during absorption of infrared rays. In general, the uncooled infrared sensor is classified into pyroelectric, thermopile, and bolometer type sensors. The uncooled infrared sensor has lower resolution of sensing infrared rays than the cooled infrared sensor but does not require an additional cooling system. Thus, the uncooled infrared sensor has the advantages of small size, low power consumption and low price for the wider application.

Bolometer is the most widely used uncooled infrared sensor and detects an increase in a resistance of a metal thin film such as titanium (Ti) or a decrease in a resistance of a semiconductor thin film such as vanadium oxide (VOₓ) or amorphous silicon (Si) when heat is generated by the absorption of infrared rays. A resistor thin film (called a resistive layer) is formed on an insulator membrane which floats at a predetermined space above a silicon substrate on which an infrared detection circuit is formed. Thus, the resistor layer is thermally isolated from the silicon substrate so as to further effectively sense heat generated during the absorption of infrared rays.

The insulator membrane is manufactured by surface micromachining technology using a sacrificial layer such as polyimide, which is coated and patterned on the silicon substrate. Next, an insulating thin film is deposited on the patterned sacrificial layer, and then only the sacrificial layer is selectively removed to form an air gap. Here, a metal reflective layer such as aluminum (Al) is formed on a surface of the silicon substrate, and the air gap is adjusted to λ/4 (where λ denotes an infrared wavelength to be sensed and is generally within a range between 8 μm and 12 μm) for a maximum absorption of infrared rays on the membrane with the resistor layer.

A structure of the bolometer depends on a type of a resistor, and thus an amorphous silicon bolometer using amorphous silicon as a resistor will be described herein.

FIG. 1 is a cross-sectional view of a conventional amorphous silicon bolometer. Referring to FIG. 1, the conventional amorphous silicon bolometer includes a substrate 122 and a sensor structure 120 which floats above the substrate 122 at an air gap of λ/4 where λ denotes an infrared wavelength. Both ends of the sensor structure 120 are fixed to the substrate 122 by metal posts 1 24. A metal pad 128 formed of Al and a metal reflective layer 126 are disposed on the substrate 122 to be electrically connected to a detection circuit. The sensor structure 120 includes an amorphous silicon resistive layer 136 doped with dopant, an absorption layer 132 formed of metal such as Ti or NiCr, and lower and upper insulating layers 130 and 134 formed of SiO₂ or Si₃N₄. Here, the absorption layer 132 is enclosed and protected by the lower and upper insulating layers 130 and 134. Both ends of the resistive layer 136 are connected to the detection circuit by metal electrodes 138a and 138b through the metal posts 124, the metal pad 128, and the reflective layer 126.

FIG. 2 is a plan view illustrating a conventional amorphous silicon bolometer. Here, a sensor structure may be the same as the sensor structure 120 of FIG. 1.

Referring to FIG. 2, both ends of the sensor structure 120 are fixed to a substrate by support arms 142 through metal tabs 144 and posts 124. Here, the support arms 142 are formed at a predetermined air gap 146 from the sensor structure 120 to prevent heat leakage from the sensor structure 120 to the substrate.

A performance of the bolometer depends on a structure of the sensor structure 120 and a characteristic of the resistive layer 136. In detail, the structure of the sensor structure 120 must have high infrared absorption, high thermal isolation, and low thermal mass. This is to prevent heat generated during the absorption of infrared rays from leaking to the substrate so as to rapidly sense the heat. The resistive layer 136 must have a high temperature coefficient of resistance (TCR) to increase variations of a resistance with variations of temperature and have low 1/f noise to have a low noise equivalent temperature difference (NETD). Temperature resolution, which is the most important performance of an infrared sensor, is generally represented as NETD.

In general, 1/f noise of a resistor is generated by carrier trapping caused by defects in a thin film. Thus, 1/f noise is reduced in order of amorphous, polycrystalline, and single crystalline thin films of which crystallinity is increased in the same order. Thus, if a polycrystalline thin film is used instead of an amorphous thin film to manufacture a bolometer using a silicon resistor, 1/f noise may be reduced to improve temperature resolution of an infrared sensor.

However, a high temperature process of 700° C. or more is required to form a polycrystalline silicon thin film having high crystallinity. A characteristic of a complementary metal-oxide semiconductor (CMOS) detection circuit formed on a substrate is degraded in such a high temperature. Thus, a conventional bolometer using a silicon resistor uses only an amorphous thin film having low crystallinity. Thus, a reduction of 1/f noise and an improvement of temperature resolution are limited.

### SUMMARY OF THE INVENTION

The present invention provides a bolometer capable of reducing 1/f noise and improving resolution of sensing temperature and a method of manufacturing the bolometer.

According to an aspect of the present invention, there is provided a bolometer including: a semiconductor substrate comprising a detection circuit; a reflective layer disposed in an area of a surface of the semiconductor substrate; metal pads disposed on the surface of the semiconductor substrate beside both sides of the reflective layer to keep predetermined distances from the both sides of the reflective layer; and a sensor structure forming a space corresponding to quarter of an infrared wavelength (λ/4) from a surface of the reflective layer and positioned above the semiconductor substrate, wherein the sensor structure includes: a body including a polycrystalline resistive layer formed of doped silicon (Si) or silicon germanium (Si₁₋ₓGeₓ, where x=0.2˜0.5) to be positioned above the reflective layer; and support arms positioned outside the body to be electrically connected to the metal pads.

According to another aspect of the present invention, there is provided a method of manufacturing a bolometer including: forming a detection circuit inside a semiconductor substrate; forming a reflective layer in an area of a surface of the semiconductor substrate; forming metal pads on the surface of the semiconductor substrate beside both sides of the reflective layer so as to keep predetermined distances from the reflective layer; forming a sacrificial layer having a thickness corresponding to quarter of an infrared wavelength (λ/4) on a front surface of the semiconductor substrate on which the reflective layer and the metal pads are formed; forming a sensor structure above the sacrificial layer, wherein the sensor structure comprises a polycrystalline resistive layer formed of doped silicon (Si) or silicon germanium (Si₁₋ₓGeₓ, where x=0.2˜0.5); and removing the sacrificial layer.

The sacrificial layer may be formed of polyimide. The sacrificial polyimide may be spin-coated and then cured at a temperature between 300° C. and 400° C.

The laser beams may be irradiated onto the reserved resistive layer to crystallize or re-crystallize the reserved resistive layer so as to form the polycrystalline resistive layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of an amorphous silicon resistor as an example of a conventional uncooled type infrared sensor;

FIG. 2 is a plan view of a bolometer using an amorphous silicon resistor as an example of a conventional uncooled type infrared sensor;

FIG. 3 is a cross-sectional view of a bolometer using a polycrystalline silicon resistor as an example of a uncooled type infrared sensor according to an embodiment of the present invention;

FIGS. 4A through 4H are cross-sectional views illustrating a method of manufacturing a bolometer using a polycrystalline silicon resistor according to an embodiment of the present invention.

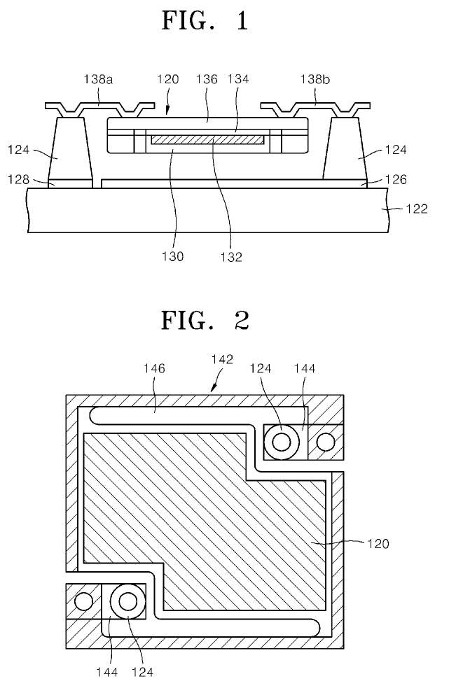

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

In the present invention, to form a resistive layer, an amorphous thin film or a polycrystalline thin film having low crystallinity is deposited. Next, laser beams are irradiated onto the amorphous or polycrystalline thin film to crystallize or re-crystallize the amorphous or polycrystalline thin film for increasing crystallinity of the resistive layer. Here, a temperature of a substrate is kept low so as not to degrade a detection circuit.

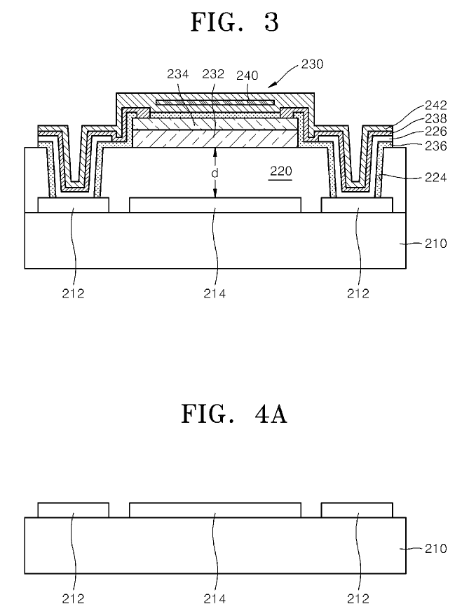

FIG. 3 is a cross-sectional view of a bolometer using a polycrystalline silicon resistor as an example of a uncooled type infrared sensor according to an embodiment of the present invention. Referring to FIG. 3, the bolometer includes a semiconductor substrate 210 having a detection circuit (not shown), a reflective layer 214 formed on a portion of a surface of the semiconductor substrate 210, and a sensor structure 230 keeping a space 220 of λ/4 from the reflective layer 214. The space 220 under the sensor structure 230 is to maximally absorb infrared rays, and λ denotes an infrared wavelength between 8 μm and 12 μm. The semiconductor substrate 210 may be formed of semiconductor silicon, and the detection circuit of the substrate 210 may be generally formed of CMOS.

Metal pads 212 are disposed beside both sides of the reflective layer 214 on the surface of the semiconductor substrate 210 to be at predetermined distances from the reflective layer 214. The metal pads 212 and the reflective layer 214 may be formed of aluminum (Al). Here, the metal pads 212 are connected to the detection circuit formed inside the semiconductor substrate 210.

The sensor structure 230 is divided into a body and a support arm. The body has a structure in which a first insulating layer 232, a resistive layer 234, a second insulating layer 236, an electrode 238, an absorptive layer 240, and a third insulating layer 242 are sequentially stacked. The support arms have a structure in which the second insulating layer 236, the electrode 238, and the third insulating layer 242 are stacked and are mechanically and electrically connected to the metal pads 212 formed on the surface of the semiconductor substrate 210. In other words, the body is disposed above the reflective layer 214 to form the space 220, and the support arms are positioned outside the reflective layer 214.

The first insulating layer 232 may be formed of SiO₂ having low thermal conductivity and have a relatively thicker thickness than the second and third insulating layers 236 and 242, preferably, a thickness between 200 nm and 500 nm. The second and third insulating layers 236 and 242 may be formed of SiO₂ or Si₃N₄ and have a relatively thinner thickness than the first insulating layer 232, preferably, a thickness between 50 nm and 200 nm.

The resistive layer 234 may be formed of polycrystalline doped Si or Si₁₋ₓGeₓ (where x=0.2˜0.5) and have a thickness between 100 nm and 250 nm. The electrode 238 may be formed of a single layer or a compound layer formed of Al, TiW, or NiCr and have a thickness between 20 nm and 100 nm. The absorptive layer 240 may be formed of a single or compound layer formed of Ti, NiCr, or TiN. The absorptive layer 240 may have a sheet resistance of 377±30 Ω/cm² to maximally absorb infrared rays and have a thickness between 10 nm and 50 nm.

An auxiliary electrode 226 may be formed underneath the electrode 238 around holes 224. This is because the electrode 238 having a thin thickness have difficulty securing step coverage and thus an electrical connection between the metal pads 212 and the resistive layer 234 may be unstable. The auxiliary electrode 226 may be formed of Al having a thickness between 200 nm and 500 nm.

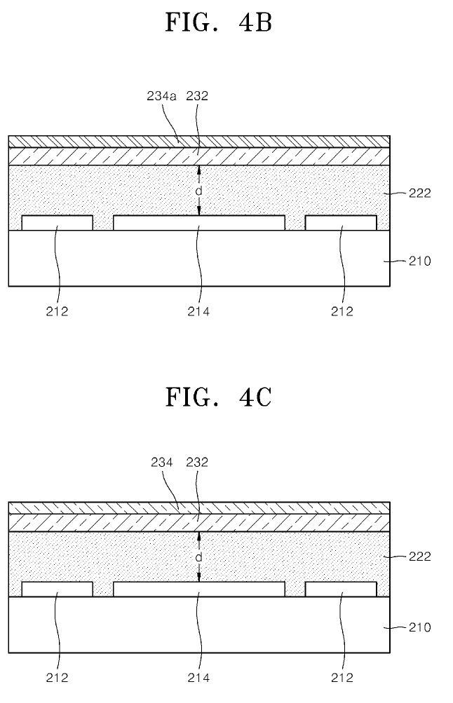

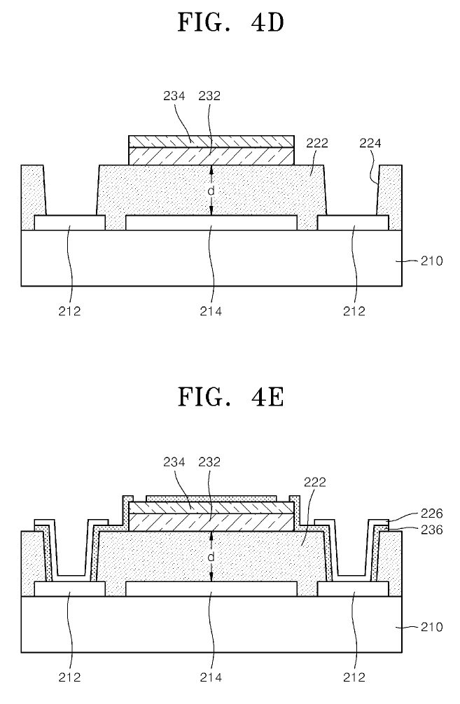

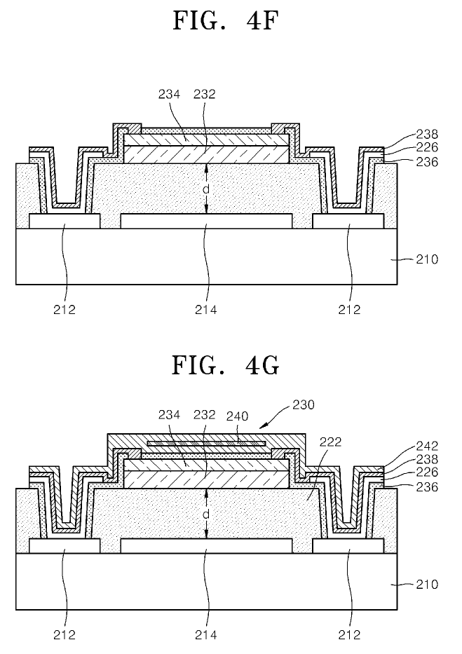

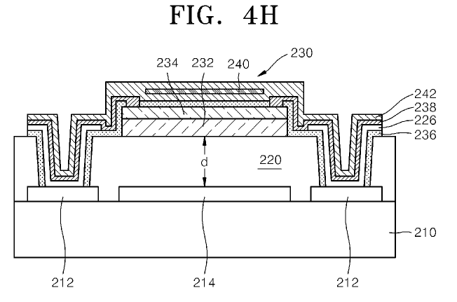

FIGS. 4A through 4H are cross-sectional views illustrating a method of manufacturing the bolometer of FIG. 3.

Referring to FIG. 4A, the silicon substrate 210 having the detection circuit (not shown) formed of CMOS is provided. The reflective layer 214 and the metal pads 212 are formed on the surface of the silicon substrate 210. Here, the metal pads 212 keep the predetermined distances from the both sides of the reflective layer 214. The metal pad 212 and the reflective layer 214 may be formed of Al having good surface reflectivity and conductivity, e.g., may be simultaneously formed through deposition. Here, the metal pads 212 are electrically connected to the detection circuit.

Referring to FIG. 4B, a sacrificial layer 222, the first insulating layer 232, and a reserved resistive layer 234a are sequentially formed on the silicon substrate 210. Here, the sacrificial layer 222 is removed in a subsequent process and may be formed of polyimide. Spin-coating is performed to thickness d corresponding to λ/4, and curing is performed at a temperature between 300° C. and 400° C. to form the sacrificial layer 222. Here, λ denotes an infrared wavelength between 8 μm and 12 μm.

The first insulating layer 232 may be formed of SiO₂ using plasma enhanced chemical vapor deposition (PECVD) or sputtering. The first insulating layer 232 may also have a thickness between 200 nm and 500 nm. The preliminary resistive layer 234a may be formed of doped Si or Si₁₋ₓGeₓ (where x=0.2˜0.5). The preliminary resistive layer 234a may be an amorphous or polycrystalline thin film deposited at a temperature of 400° or less using CVD or sputtering, wherein the polycrystalline thin film has low crystallinity. The preliminary resistive layer 234a may have a thickness between 100 nm and 250 nm.

Referring to FIG. 4C, XeCl excimer laser beams having a wavelength λ of 308 nm are irradiated onto the preliminary resistive layer 234a to heat the reserved resistive layer 234a at a temperature above 700° C. so as to crystallize or re-crystallize the preliminary resistive layer 234a. As a result, the preliminary resistive layer 234a is converted into a polycrystalline resistive layer 234 having high crystallinity. Here, the temperature of the silicon substrate 210 is kept low so as not to degrade the detection circuit. In other words, the polycrystalline resistive layer 234 have higher crystallinity than the preliminary resistive layer 234a. 1/f noise of the polycrystalline resistive layer 234 is reduced, and temperature resolution of the bolometer is improved due to the low temperature crystallization using laser beams.

Referring to FIG. 4D, the polycrystalline resistive layer 234, the first insulating layer 232, and the sacrificial layer 222 are sequentially etched to form the holes 224 exposing the metal pads 212. The polycrystalline resistive layer 234 and the first insulating layer 232 are etched to form the body of the sensor structure 230. As a result, the body of the sensor structure 230 is positioned at a distance of λ/4 from the reflective layer 214.

Referring to FIG. 4E, the second insulating layer 236 is formed of SiO₂ or Si₃N₄ on the first insulating 232, the polycrystalline resistive layer 234, and the sacrificial layer 222. The second insulating layer 236 is etched to expose a portion which will contact the electrode 238 shown in FIG. 4G. As a result, the sensor structure 230 is divided into the body and the support arms, and portions of the metal pads 212 and the polycrystalline resistive layer 234 are exposed due to etching. The auxiliary electrode 226 may be formed under the electrode 238 of FIG. 4F around the holes 224.

Referring to FIG. 4F, the electrode 238 is formed of the single or compound layer formed of Al, TiW, or NiCr above the second insulating layer 236 to a uniform thickness. The electrode 238 is etched to connect the exposed metal pads 212 to the polycrystalline resistive layer 234. As a result, the second insulating layer 236 is positioned on the polycrystalline resistive layer 234 between the electrode 238.

Referring to FIG. 4G, the absorptive layer 240 is formed of Ti, NiCr, or TiN on the polycrystalline resistive layer 234 between the electrode 238 using a normal method so as to be enclosed by the third insulating layer 242. Thus, the absorptive layer 240 is electrically insulated from the polycrystalline resistive layer 234. Here, the absorptive layer 240 is etched to remain in the body of the sensor structure 230. In other words, the third insulating layer 242 is formed of SiO₂ or Si₃N₄ to cover the absorptive layer 240 and the electrode 238. The third insulating layer 242 is etched to leave the body and the support arms of the sensor structure 230.

Referring to FIG. 4H, the sacrificial layer 220 is removed using plasma ashing using a mixture gas including O₂. Thus, the space 220 corresponding to the thickness d of the sacrificial layer 220 is formed between the reflective layer 214 and the body of the sensor structure 230.

As described above, in a bolometer and a method of manufacturing the bolometer according to the present invention, a resistive layer can be formed of polycrystalline Si or Si₁₋ₓGeₓ having increased crystallinity on a substrate including a detection circuit. Thus, 1/f noise can be reduced without degrading the detection circuit. As a result, resolution of sensing temperature can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A bolometer comprising:
a semiconductor substrate comprising a detection circuit;
a reflective layer disposed in an area of a surface of the semiconductor substrate;
metal pads disposed on the surface of the semiconductor substrate beside both sides of the reflective layer to keep predetermined distances from the both sides of the reflective layer; and
a sensor structure forming a space corresponding to quarter of an infrared wavelength (λ/4) from a surface of the reflective layer and positioned above the semiconductor substrate,
wherein the sensor structure comprises:
a body comprising a polycrystalline resistive layer formed of one of doped Si and Si₁₋ₓGeₓ (where x=0.2˜0.5) to be positioned above the reflective layer; and
support arms positioned outside the body to be electrically connected to the metal pads.

2. The bolometer of claim 1, wherein the body has a structure in which a first insulating layer, a resistive layer, a second insulating layer, an electrode, an absorptive layer, and a third insulating layer are sequentially stacked, and the support arms have a structure in which the second insulating layer, the electrode, and the third insulating layer are sequentially stacked.

3. The bolometer of claim 1, wherein the infrared wavelength is within a range between 8 μm and 12 μm.

4. The bolometer of claim 2, wherein the first insulating layer is formed of SiO₂ having low thermal conductivity.

5. The bolometer of claim 2, wherein the second and third insulating layers are formed of one of SiO₂ and Si₃N₄.

6. The bolometer of claim 2, wherein the electrode is formed of one of single and compound layers formed of one of Al, TiW, and NiCr.

7. The bolometer of claim 2, wherein the absorptive layer is formed of one of single and compound layers formed of one of Ti, NiCr, and TiN.

8. The bolometer of claim 2, wherein the first insulating layer has a thickness between 200 nm and 500 nm.

9. A method of manufacturing a bolometer, comprising:
forming a detection circuit inside a semiconductor substrate;
forming a reflective layer in an area of a surface of the semiconductor substrate;
forming metal pads on the surface of the semiconductor substrate beside both sides of the reflective layer so as to keep predetermined distances from the reflective layer;
forming a sacrificial layer having a thickness corresponding to quarter of an infrared wavelength (λ/4) on a front surface of the semiconductor substrate on which the reflective layer and the metal pads are formed;
forming a sensor structure above the sacrificial layer, wherein the sensor structure comprises a polycrystalline resistive layer formed of one of doped Si and Si₁₋ₓGeₓ (where x=0.2˜0.5); and
removing the sacrificial layer.

10. The method of claim 9, wherein the sacrificial layer is formed of polyimide.

11. The method of claim 10, wherein the polyimide is coated using spin-coating and then cured at a temperature between 300° C. and 400° C. to form the sacrificial layer.

12. The method of claim 9, wherein the formation of the sensor structure comprises:
sequentially forming a first insulating layer and a preliminary resistive layer on the sacrificial layer;
irradiating laser beams onto the preliminary resistive layer to form a polycrystalline resistive layer;
sequentially removing portions of the polycrystalline resistive layer, the first insulating layer, and the sacrificial layer;
etching the polycrystalline resistive layer and the first insulating layer to define the polycrystalline resistive layer and the first insulating layer on a reflective layer;
forming a second insulating layer to a uniform thickness so as to cover the first insulating layer, the polycrystalline resistive layer, and the sacrificial layer;
removing the second insulating layer to expose a portion of a surface of the polycrystalline resistive layer;
forming an electrode which electrically connects the polycrystalline resistive layer to the metal pads;
forming an absorptive layer on the exposed second insulating layer; and
forming a third insulating layer covering the electrode, the second insulating layer, and the absorptive layer.

13. The method of claim 12, wherein the preliminary resistive layer is formed of one of doped Si and Si₁₋ₓGeₓ (where x=0.2˜0.5), wherein Si and Si₁₋ₓGeₓ have amorphous or low crystalline state.

14. The method of claim 12, wherein the preliminary resistive layer is formed at a temperature of 400° or less using one of chemical vapor deposition (CVD) and sputtering.

15. The method of claim 12, wherein the laser beams are irradiated onto the preliminary resistive layer to crystallize or re-crystallize the reserved resistive layer so as to form the polycrystalline resistive layer.

16. The method of claim 12, wherein the laser beams are excimer laser beams.
